(19) United States
(12) Patent Application Publication
(10) Pub. No.: US 2015/0048336 A1
(43) Pub. Date: Feb. 19, 2015

(54) ORGANIC ELECTROLUMINESCENCE PANEL AND METHOD FOR PRODUCING THE SAME

(71) Applicant: Yohei Tanaka, Kawasaki-shi (JP)

(72) Inventor: Yohei Tanaka, Kawasaki-shi (JP)

(73) Assignee: PIONEER CORPORATION, Kawasaki-shi, Kanagawa (JP)

(21) Appl. No.: 14/383,045

(22) PCT Filed: Apr. 2, 2012
(86) PCT No.: PCT/JP2012/058961

§ 371 Date: Oct. 3, 2014

(51) Int. Cl. H01L 51/52; H01L 51/56; H01L 51/00

(52) U.S. Cl. CPC H01L 51/5212; H01L 51/0097; H01L 51/56; H01L 51/0021; H01L 51/5215; H01L 2251/558
USPC 257/40; 438/46

(57) ABSTRACT

In an organic EL panel, a transparent conductive film, a functional layered body including at least one light-emitting layer, and an opposing electrode film are layered in this order on a substrate, and the light-emitting layer which overlaps the transparent conductive film and the opposing electrode film serves as a light-emitting portion. The organic EL panel has at least one auxiliary electrode that is formed on the substrate below the light-emitting portion and directly covered with the transparent conductive film. The transparent conductive film has a film thickness more than that of the auxiliary electrode and the side surface of the transparent conductive film is covered with the functional layered body.

### TECHNICAL FIELD

The present invention relates to an organic electroluminescence (hereinafter referred to as organic EL) panel having a light-emitting layer containing an organic EL material and a method for producing the same.

### BACKGROUND ART

An organic EL element is used in a display device as a light-emitting body in which a plurality of functional layers such as a hole injection layer, a hole transport layer, a light-emitting layer, an electron transport layer, and an electron injection layer are disposed between an anode and a cathode. An organic EL panel is a surface light-emitting body in which the area of organic EL element is enlarged.

A display device in which a plurality of organic EL elements are arranged in a matrix on a substrate is provided with an insulating film, such as a partition wall and a bank, for compartment into each element (see Patent Documents 1 to 3).

### CITATION LIST

### Patent Documents

Patent Document 1: Japanese Patent Application Laid-Open No. 2000-195680
Patent Document 2: Japanese Patent Application Laid-Open No. 2007-149578
Patent Document 3: Japanese Patent Application Laid-Open No. 2011-216317

### SUMMARY OF THE INVENTION

### Problem to be Solved by the Invention

In a step of producing a conventional display device, an anode of an organic EL element is often patterned on a substrate by an etching method such as photolithography. In this case, the anode has a steep edge shape, and is unstable. Therefore, an insulating film that covers the anode edge is necessary to prevent short circuit between the anode and a cathode and suppress breaking of the cathode. However, an insulating film forming step is added when an organic EL element includes such an insulating film, and therefore, a factor of degrading a manufacturing yield is also added because of the additional step. Accordingly, there is a problem in which the cost of an organic EL panel cannot be decreased.

The specific resistance of a transparent anode of an organic EL element is high. Therefore, even if an auxiliary electrode is provided on the transparent anode to suppress voltage drop, the auxiliary electrode is often patterned by an etching method such as photolithography. There has been a proposal in which an electrically insulating material is filled in a space between parallel conductive bus lines having steep edges also in this case so as to be made flat (see Patent Document 1). However, when an electrically insulating film is provided between the conductive bus lines of the organic EL element, light generated by a light-emitting portion is absorbed by the insulating film. The area of a region where the generated light is guided outside is restricted, and electric power is wastefully consumed. Specifically, a portion that is comparted by the insulating film is a region where light is radiated outside as it is. Therefore, the aperture ratio decreases, and as a result, there is a problem in which the power consumption must be increased to obtain a desired amount of light.

The present invention has been made in view of such a problem. An object to be achieved by the present invention is to provide an organic EL panel that can be produced at low cost and increase the aperture ratio and a method for producing the same.

### Means to Solve the Problem

An organic EL panel of the present invention is an organic EL panel including a substrate, a transparent conductive film layered on the substrate, a functional layered body that is layered on the transparent conductive film and includes at least one light-emitting layer, and an opposing electrode film layered on the functional layered body, wherein the light-emitting layer that is disposed between the transparent conductive film and the opposing electrode film and overlaps the transparent conductive film and the opposing electrode film serves as a light-emitting portion. The organic EL panel has at least one auxiliary electrode that is formed on the substrate below the light-emitting portion and directly covered with the transparent conductive film. The transparent conductive film has a film thickness more than that of the auxiliary electrode. A side surface of the transparent conductive film is covered with the functional layered body.

A method for producing the above-described organic EL panel of the present invention is a method for producing an organic EL panel, the organic EL panel including a substrate, a transparent conductive film layered on the substrate, a functional layered body that is layered on the transparent conductive film and includes at least one light-emitting layer, and a opposing electrode film layered on the functional layered body, wherein the light-emitting layer that is disposed between the transparent conductive film and the opposing electrode film and overlaps the transparent conductive film and the opposing electrode film serves as a light-emitting portion, the method including the steps of: forming at least one auxiliary electrode on part of a main surface of the substrate; forming the transparent conductive film on the substrate and the auxiliary electrode; and forming the functional layered body that covers the transparent conductive film. In the step of forming the transparent conductive film, the transparent conductive film is formed by a wet coating method or a sputtering method using a mask so that the transparent conductive film has a film thickness more than that of the auxiliary electrode and the auxiliary electrode is completely covered with the transparent conductive film below the light-emitting portion.

According to the present invention, the organic EL panel includes at least one auxiliary electrode that is formed on the substrate in part of the light-emitting portion and directly covered with the transparent conductive film, and does not have an insulating film. Therefore, the aperture ratio of the organic EL panel can be improved as compared with a conventional element. Further, light generated can be efficiently radiated, and therefore, the power consumption can be decreased as compared with a conventional organic EL panel.

### BRIEF DESCRIPTION OF DRAWINGS

FIG. 1 is a plan view taken from a top perspective part showing a structure of an organic EL panel according to an embodiment of the present invention.

FIG. 2 is a partial cross-sectional view taken along line A-A of FIG. 1.

FIG. 3 is a cross-sectional view showing a substrate and a structure formed on the substrate in a production process of an organic EL panel according to an embodiment of the present invention.

FIG. 4 is a cross-sectional view showing the substrate and a structure formed on the substrate in the production process of the organic EL panel according to the embodiment of the present invention.

FIG. 5 is a cross-sectional view showing the substrate and a structure formed on the substrate in the production process of the organic EL panel according to the embodiment of the present invention.

FIG. 6 is a cross-sectional view showing the substrate and a structure formed on the substrate in the production process of the organic EL panel according to the embodiment of the present invention.

FIG. 7 is a cross-sectional view showing the substrate and a structure formed on the substrate in the production process of the organic EL panel according to the embodiment of the present invention.

FIG. 8 is a cross-sectional view showing the substrate and a structure formed on the substrate in the production process of the organic EL panel according to the embodiment of the present invention.

FIG. 9 is a cross-sectional view showing the substrate and a structure formed on the substrate in the production process of the organic EL panel according to the embodiment of the present invention.

FIG. 10 is a cross-sectional view showing the substrate and a structure formed on the substrate in the production process of the organic EL panel according to the embodiment of the present invention.

FIG. 11 is a cross-sectional view showing a substrate and a structure formed on the substrate in a production process of an organic EL panel according to another embodiment of the present invention.

FIG. 12 is a cross-sectional view showing the substrate and a structure formed on the substrate in the production process of the organic EL panel according to the other embodiment of the present invention.

### DESCRIPTION OF EMBODIMENTS

An organic EL panel according an embodiment of the present invention will be described below with reference to the drawings.

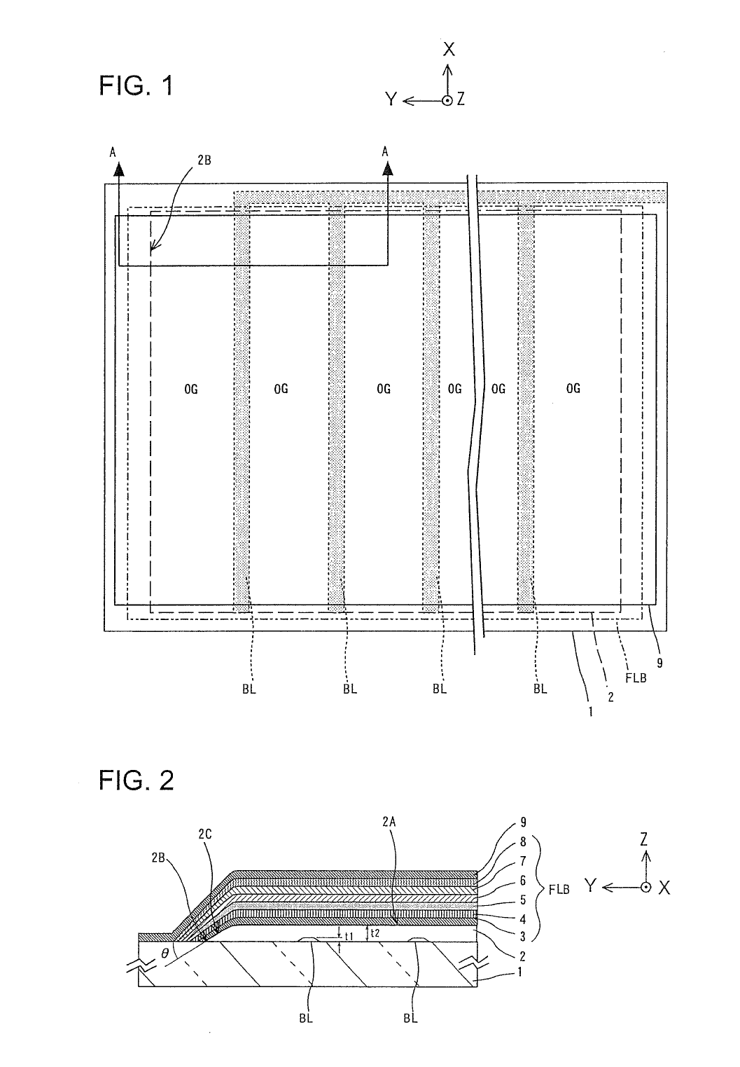

FIG. 1 is a plan view taken from a perspective part when part of the organic EL panel according to an embodiment of the present invention is seen from a top of a cathode side. FIG. 2 is a partial cross-sectional view showing the cross-section of the organic EL panel along line A-A of FIG. 1.

As shown in FIG. 2, the organic EL panel includes a transparent anode 2 (so-called transparent conductive film) that is formed on a flat-shaped transparent substrate 1 made of glass, resin, or the like, on a light extraction side, a functional layered body FLB that is layered on the anode, and a cathode 9 (so-called opposing electrode film) that is layered on the functional layered body. The functional layers of a functional layered body FLB capable of emitting white light may be, for example, a layered body of a hole injection layer 3/a hole transport layer 4/a light-emitting layer 5 of emitting red light and green light/a blue light-emitting layer 6/an electron transport layer 7/an electron injection layer 8.

As shown in FIGS. 1 and 2, the transparent anode 2 and the cathode 9 that are extended in X and Y directions of a panel plane are formed on the substrate 1 so that the functional layered body FLB is disposed between the anode 2 and the cathode 9. A portion of the functional layered body FLB that is disposed between the anode 2 and the cathode 9 and overlaps them serves as a light-emitting portion, the anode 2 being a transparent conductive film such as ITO and the cathode 9 being an opposing electrode film, whereby light is taken out from the substrate 1 side.

A plurality of longitudinal auxiliary electrodes BL are formed in parallel and in stripes on the substrate 1 under the transparent anode 2 so as to be extended in the X direction. Specifically, the auxiliary electrodes BL on the substrate 1 are formed so as to be directly covered with the anode 2 and electrically connected to the anode 2. The auxiliary electrodes BL are formed to supply power from a power source to the anode 2. A short circuit-preventing film (not shown) may be provided on the portions of the auxiliary electrodes BL that are exposed to the outside of the light-emitting portion from the anode 2 and a connection wiring thereof between the end portion of the cathode 9, that is, on the auxiliary electrodes BL except the light-emitting portion. In an organic EL panel for a surface light source, even when it is required that the specific resistance of a transparent electrode is high and the area thereof is large, auxiliary electrodes made of a metal material having low specific resistance are arranged in stripes under the transparent electrode to totally decrease the resistance of the auxiliary electrodes BL and the transparent anode 2.

The plurality of auxiliary electrodes BL are provided in the lower portion of the transparent anode 2 to increase the film thickness of the transparent anode 2 to a μm-scale of more than 1 μm. Thus, in the organic EL panel of the embodiment, the resistance decreases and the coverage effect of the auxiliary electrodes BL increases to make the anode itself smooth. A smooth main surface obtained by an increase in the film thickness of the anode contributes to smoothing of a functional layer of the functional layered body FLB, which is formed during a post-process, and a reduction in uneven film thickness. In addition to the smoothing, an effect of reducing interference of the light extraction side is also expected by the increase in the film thickness of the anode. For example, in setting of the film thickness of the anode, the flexibility of film thickness can be increased to non-integral multiple of a quarter of the peak wavelength of each extracted light-emitting color. In order to increase the film thickness of the anode, the anode 2 has a film thickness t2 more than the film thickness t1 of the auxiliary electrodes BL, as shown in FIG. 2. It is preferable that the film thickness of the transparent anode 2 be 1 μm to 5 μm to maintain the transmissivity of the transparent anode 2 and secure the panel property.

As shown in FIG. 2, the anode 2 is formed so as to have, at the interface with the functional layered body FLB, a smooth main surface 2A and a tapered side surface 2C in which the film thickness gradually decreases toward an edge portion 2B (the outermost edge) of the anode 2 on the main surface of the substrate 1. Herein, the anode is usually patterned by a photolithography process. Since an edge of an ITO anode produced by the process is unstable, the anode needs to be covered with an insulating film. A processing step for this insulating film is one factor of increasing the cost of a panel and reducing a yield ratio. In order to solve this problem, it is preferable that the anode be patterned by screen printing, a wet coating method such as printing not using a plate and printing using a plate, or a sputtering method using a contactless or contact mask. Further, it is preferable that the functional layers of the functional layered body FLB be formed by coating. When the functional layered body FLB is formed on the tapered side surface 2C of the anode 2, a tapered side surface is formed also in the functional layered body FLB, and breaking of the cathode to be formed during the post-process can be prevented. According to the configuration described above, an organic EL panel suitable for lighting or the like without an insulating film can be produced.

The functional layers of the functional layered body FLB are formed by coating to improve the coverage of the anode 2 and the edge portion 2B. In particular, it is preferable that a first layer (the hole injection layer 3 or the hole transport layer 4) of the functional layered body FLB be formed so as to have a film thickness more than that of the auxiliary electrodes BL. As the functional layered body FLB at the tapered side surface is made thicker, the coverage property of the anode 2 and the edge portion 2B increases, and therefore, a leak suppressing effect increases. Specifically, it is preferable that the total film thickness of layered films from the anode 2 to a light-emitting layer 5 of the functional layered body FLB be at least 100 nm to secure a property of embedding a foreign substance on the anode.

As shown in FIG. 2, one example of the organic EL panel of the embodiment is a configuration in which the anode 2/the hole injection layer 3/the hole transport layer 4/the light-emitting layer 5 of emitting red light and green light/the blue light-emitting layer 6/the electron transport layer 7/the electron injection layer 8/the cathode 9 are layered in this order on the transparent substrate 1 such as glass. In addition to this layer configuration, the present invention includes: a configuration excluding the hole transport layer 4, i.e., a configuration of the anode 2/the hole injection layer 3/the light-emitting layer 5 of emitting red light and green light/the blue light-emitting layer 6/the electron transport layer 7/the electron injection layer 8/the cathode 9, that is not shown; a configuration excluding the hole injection layer 3, i.e., a configuration of the anode 2/the hole transport layer 4/the light-emitting layer 5 of emitting red light and green light/the blue light-emitting layer 6/the electron transport layer 7/the electron injection layer 8/the cathode 9, that is not shown; and a configuration the hole injection layer 3 and the electron transport layer 7, i.e., a configuration of the anode 2/the hole transport layer 4/the light-emitting layer 5 of emitting red light and green light/the blue light-emitting layer 6/the electron injection layer 8/the cathode 9, that is not shown. Further, the present invention includes a configuration in which a diffusion prevention layer is provided between the light-emitting layer 5 of emitting red light and green light and the blue light-emitting layer 6 in the layer configurations.

As a process for forming the functional layers of the organic EL panel, a dry coating method such as a sputtering method and a vacuum deposition method and a wet coating method such as screen printing, a spraying method, an inkjet method, a spin coater method, gravure printing, and a roll coater method are known. For example, the hole injection layer, the hole transport layer, and the light-emitting layer may be uniformly formed as full-coating films by the wet coating method, and the electron transport layer and the electron injection layer may be uniformly formed as full-coating films sequentially by the dry coating method. Further, all functional layers may be uniformly formed as full-coating films sequentially by the wet coating method.

As the substrate 1, a plate of quartz glass or glass, a metal plate, a metal foil, a flexible resin substrate, a plastic film or sheet, or the like, can be used. In particular, a glass plate, and a transparent plate of synthetic resin such as polyester, polymethacrylate, polycarbonate, or polysulfone are preferable. When using a synthetic resin substrate, attention should be paid to the gas barrier property. When the gas barrier property of the substrate is too small, the organic EL panel may be deteriorated by air that passes through the substrate. Therefore, such a substrate is not preferable. Accordingly, one of preferable methods is a method in which a dense silicon oxide film or the like is provided on at least one surface of the synthetic resin substrate to ensure the gas barrier property.

When the thick transparent anode is formed by the wet coating method, an irregular surface of the substrate can be alleviated. Therefore, an inexpensive glass substrate that is not an expensive polished glass substrate for a display may also be used as a substrate of an organic EL panel.

### [Anode and Cathode]

The anode 2 that supplies a hole to the functional layers that are up to a light-emitting layer is usually made from a complex oxide (so-called ITO) of indium oxide and tin oxide, or the like. In addition to ITO, the anode 2 may be made from ZnO, ZnO—Al₂O₃ (so-called AZO), In₂O₂—ZnO (so-called IZO), SnO₂—Sb₂O₃ (so-called ATO), RuO₂, or the like. It is preferable that a material having a transmissivity of at least 10% or more in the wavelength of light emitted from an organic EL material be selected for a transparent conductive film of the anode 2.

The anode usually has a single-layer structure, but if desired, may have a layered structure made from a plurality of materials.

In order to remove impurities attached to the anode and adjust ionization potential to improve the hole injection property, it is preferable that the surface of the anode be treated with ultraviolet (UV)/ozone, oxygen plasma, or argon plasma.

It is preferable that a material for the cathode 9 that supplies an electron to the functional layers that are up to a light-emitting layer be metal having a low work function to effectively inject an electron. For example, appropriate metal such as tin, magnesium, indium, calcium, aluminum, or silver, or an alloy thereof is used. Specifically, an electrode made of an alloy having a low work function, such as a magnesium-silver alloy, a magnesium-indium alloy, or an aluminum-lithium alloy, is used.

One kind of the material for the cathode 9 may be used alone, or two or more kinds thereof may be used in combination at any ratio.

For the purpose of protecting the cathode made of metal having a low work function, a metal layer that has a high work function and is stable to the air is layered on the cathode. This is because the stability of the organic EL panel increases, and therefore it is preferable. For example, metal such as aluminum, silver, copper, nickel, chromium, gold, or platinum may be used for this purpose. One kind of the material may be used alone, or two or more kinds thereof may be used in combination at any ratio.

### [Functional Layer of Functional Layered Body]

### [Hole Injection Layer]

It is preferable that the hole injection layer 3 be a layer containing an electron-accepting compound.

When the hole injection layer is formed by the wet coating method, a composition for formation of a hole injection layer usually contains a hole-transporting compound and a solvent as constituent materials of a hole injection layer. Examples of the solvent may include, but be not limited to, an ether solvent, an ester solvent, an aromatic hydrocarbon-based solvent, and an amide solvent. Examples of the ether solvent may include aliphatic ethers such as ethylene glycol dimethyl ether, ethylene glycol diethyl ether, and propylenegylcol monomethyl ether acetate (so-called PGMEA), and aromatic ethers such as 1,2-dimethoxybenzene, 1,3-dimethoxybenzene, anisole, phenetole, 2-methoxytoluene, 3-methoxytoluene, 4-methoxytoluene, 2,3-dimethylanisole, and 2,4-dimethylanisole.

Examples of the ester solvent may include aromatic esters such as phenyl acetate, phenyl propionate, methyl benzoate, ethyl benzoate, propyl benzoate, and n-butyl benzoate.

Examples of the aromatic hydrocarbon-based solvent may include toluene, xylene, cyclohexylbenzene, 3-isoprophylbiphenyl, 1,2,3,4-tetramethylbenzene, 1,4-diisopropylbenzene, cyclohexylbenzene, and methylnaphthalene.

Examples of the amide solvent may include N,N-dimethylformamide and N,N-dimethylacetamide. In addition, dimethylsulfoxide can be used. One kind of the solvent may be used alone, or two or more kinds thereof may be used in combination at any ratio.

The hole-transporting compound may be usually a macromolecular compound such as a polymer or a low molecular compound such as a monomer as long as it is a compound having hole-transporting property that is used for the hole injection layer of the organic EL panel. It is preferable that the hole-transporting compound be a low molecular compound.

From the viewpoint of charge injection barrier from the anode into the hole injection layer, it is preferable that the hole-transporting compound be a compound having an ionization potential of 4.5 eV to 6.0 eV. Examples of the hole-transporting compound may include aromatic amine derivatives, phthalocyanine derivatives typified by copper phthalocyanine (so-called CuPc), porphyrin derivatives, oligothiophene derivatives, polythiophene derivatives, benzyl phenyl derivatives, compounds having a tertiary amine connected through a fluorene group, hydrazone derivatives, silazane derivatives, silanamine derivatives, phosphamine derivatives, quinacridone derivatives, polyaniline derivatives, polypyrrole derivatives, polyphenylenevinylene derivatives, polythienylenevinylene derivatives, polyquinoline derivatives, polyquinoxaline derivatives, and carbon. The derivative used herein includes, for example, in the case of an aromatic amine derivative, an aromatic amine itself and a compound having an aromatic amine as a main skeleton, and the derivative may be a polymer or a monomer.

As the hole-transporting compound, a conductive polymer (so-called PEDOT/PSS) obtained by polymerizing 3,4-ethylenedioxythiophene as a polythiophene derivative in a high-molecular-weight polystyrenesulfonic acid is also preferable. Further, the terminal of the polymer of PEDOT/PSS may be capped with methacrylate or the like.

Any one of the hole-transporting compounds used as a material for the hole injection layer may be contained alone, or two or more thereof may be contained. When two or more kinds of hole-transporting compounds are contained, any combination may be employed. One kind or two or more kinds of aromatic tertiary amine macromolecular compounds and one kind or two or more kinds of other hole-transporting compounds can be used in combination. In view of amorphous property and transmissivity of the visible light, an aromatic amine compound is preferable, and an aromatic tertiary amine compound is particularly preferable for the hole injection layer. The aromatic tertiary amine compound used herein is a compound having an aromatic tertiary amine structure and includes also a compound having a group derived from an aromatic tertiary amine.

In view of uniformity of the film thickness, the concentration of the hole transporting compound in the composition for formation of a hole injection layer is usually 0.01% by weight or more, preferably 0.1% by weight or more, and more preferably 0.5% by weight or more, and usually 70% by weight or less, preferably 60% by weight or less, and more preferably 50% by weight or less. When the concentration is too high, the film thickness may be made uneven. In contrast, when the concentration is too low, a defect may be generated in the hole injection layer to be formed.

It is preferable that the composition for formation of a hole injection layer contain an electron-accepting compound. In addition to the hole-transporting compound and the electron-accepting compound, another component may be contained. Examples of the other components may include various organic EL materials, electron-transporting compounds, binder resins, and agents for improving application property. One kind of the other components may be used alone, or two or more kinds thereof may be used in combination at any ratio.

In general, when the hole injection layer is formed by the wet coating method, a material constituting the hole injection layer is mixed with an appropriate solvent (solvent for a hole injection layer) to prepare a composition for film formation (composition for formation of a hole injection layer), and the composition for formation of a hole injection layer is applied to the anode by an appropriate method to form a film, and then dried to form a hole injection layer.

The film thickness of the hole injection layer falls within a range of usually 5 nm or more, and preferably 10 nm or more, and usually 1,000 nm or less, and preferably 500 nm or less.

### [Hole Transport Layer]

As a material for the hole transport layer 4, a material conventionally used as a constituent material for a hole transport layer may be used. Examples thereof may include those described above as examples of the hole-transporting compound used in the hole injection layer. Further, examples thereof may include arylamine derivatives, fluorene derivatives, spiro derivatives, carbazole derivatives, pyridine derivatives, pyrazine derivatives, pyrimidine derivatives, triazine derivatives, quinoline derivatives, phenanthroline derivatives, phthalocyanine derivatives, porphyrin derivatives, silole derivatives, oligothiophene derivatives, condensed polycyclic aromatic derivatives, and metal complexes. Furthermore, examples thereof may include polyvinyl carbazole derivatives, polyarylamine derivatives, polyvinyl triphenylamine derivatives, polyfluorene derivatives, polyarylene derivatives, polyarylene ether sulfone derivatives containing tetraphenyl benzidine, polyarylene vinylene derivatives, polysiloxane derivatives, polythiophene derivatives, and poly(p-phenylene vinylene) derivatives. These may be any of an alternating copolymer, a random copolymer, a block copolymer, and a graft copolymer, and may also be a polymer having a branched main chain and three or more terminal portions, so-called a dendrimer.

When the hole transport layer is formed by the wet coating method, a composition for formation of a hole transport layer is prepared in the same manner as in the formation of the hole injection layer, a film is formed by the wet coating method, and dried.

The composition for formation of a hole transport layer contains a solvent, in addition to the hole-transporting compound. The solvent used is the same as the solvent used for the composition for formation of a hole injection layer. Film formation conditions, drying conditions, and the like are also the same as those in the formation of the hole injection layer.

The hole transport layer may contain various organic EL materials, electron-transporting compounds, binder resins, agents of improving application property, and the like, in addition to the hole-transporting compound.

The film thickness of the hole transport layer is usually 5 nm or more, and preferably 10 nm or more, and usually 300 nm or less, and preferably 100 nm or less.

As described above, it is preferable that at least the hole injection layer 3 or the hole transport layer 4 be thickly formed. Therefore, it is preferable that the total film thickness of the hole injection layer 3 and/or the hole transport layer 4, from the anode 2 to the light-emitting layer 5, be at least 100 nm.

### [Light-Emitting Layer]

The light-emitting layer including the light-emitting layer of emitting red light and green light and the blue light-emitting layer may include an organic EL material, and preferably a compound having a hole-transporting property (hole-transporting compound) or a compound having an electron-transporting property (electron-transporting compound). The organic EL material may be used as a dopant material, and the hole-transporting compound, the electron-transporting compound, or the like may be appropriately used as a host material. The organic EL material is not particularly limited, and a substance emitting light at a desired emission wavelength and giving favorable light-emitting efficiency may be used.

As the organic EL material, any known material can be applied. For example, a fluorescent material or a phosphorescent material may be applied. From the viewpoint of internal quantum efficiency, the phosphorescent material is preferably used. The light-emitting layer may have a single-layer structure or if desired, a multi-layer structure made from a plurality of materials. For example, the fluorescent material is used for a blue light-emitting layer and the phosphorescent material is used for a green light-emitting layer and a red light-emitting layer. Various materials may be used in combination. Further, a diffusion prevention layer may also be provided between the light-emitting layers.

Examples of a fluorescent material exhibiting blue luminescence (blue fluorescent dye) may include naphthalene, perylene, pyrene, chrysene, anthracene, coumarin, p-bis(2-phenylethenyl)benzene, and derivatives thereof.

Examples of a fluorescent material exhibiting green luminescence (green fluorescent dye) may include quinacridone derivatives, coumarin derivatives, and aluminum complexes such as tris(8-hydroxy-quinoline)aluminum (Alq3).

Examples of a fluorescent material exhibiting yellow luminescence (yellow fluorescent dye) may include rubrene and perimidone derivatives.

Examples of a fluorescent material exhibiting red luminescence (red fluorescent dye) may include 4-(dicyanomethylene)-2-methyl-6-(p-dimethylaminostyryl)-4H-pyran (DCM)-based compounds, benzopyran derivatives, rhodamine derivatives, benzothioxanthene derivatives, and azabenzothioxanthene.

Examples of the phosphorescent material may include an organometallic complex containing metal selected from Groups 7 to 11 of the long-periodic table (hereinafter, unless particularly otherwise noted, “the periodic table” is intended to refer to the long-periodic table). Preferable examples of metal selected from Groups 7 to 11 of the periodic table may include ruthenium, rhodium, palladium, silver, rhenium, osmium, iridium, platinum, and gold. As the ligand of the complex, a ligand in which a (hetero)aryl group is coupled with pyridine, pyrazole, phenanthroline, or the like, such as a (hetero)arylpyridine ligand and a (hetero)arylpyrazole ligand is preferable, and a phenylpyridine ligand and a phenylpyrazole ligand are particularly preferable. Here, the (hetero)aryl represents an aryl group or a heteroaryl group.

Specific examples of the phosphorescent material may include tris(2-phenylpyridine) iridium (so-called Ir(ppy)₃), tris(2-phenylpyridine) ruthenium, tris(2-phenylpyridine) palladium, bis(2-phenylpyridine) platinum, tris(2-phenylpyridine) osmium, tris(2-phenylpyridine) rhenium, octaethyl platinum porphyrin, octaphenyl platinum porphyrin, octaethyl palladium porphyrin, and octaphenyl palladium porphyrin.

The molecular weight of a compound used as the organic EL material falls within a range of usually 10,000 or less, preferably 5,000 or less, more preferably 4,000 or less, and further preferably 3,000 or less, and usually 100 or more, preferably 200 or more, more preferably 300 or more, and further preferably 400 or more. When the molecular weight of the organic EL material is too small, the heat resistance may significantly reduce, the generation of gas may be caused, the quality of a film to be formed may be deteriorated, or the morphological change of the functional layers may be caused by migration or the like. In contrast, when the molecular weight of the organic EL material is too large, it is difficult to purify the organic compound, or it tends to take a long time to dissolve the compound in the solvent during formation by the wet coating method.

One kind of the organic EL material may be used alone, or two or more kinds thereof may be used in combination at any ratio. The ratio of the organic EL material in the light-emitting layer is usually 0.05% by weight or more and 35% by weight or less. When the amount of the organic EL material is too small, the luminescence may be made uneven. When it is too large, the light-emitting efficiency may decrease. When two or more kinds of organic EL materials are used in combination, the total content thereof is set within the above-described range. A component of which the content in the light-emitting layer is largest is referred to as a host material, and a component of which the content is smaller is referred to as a guest material.

The light-emitting layer may contain a hole-transporting compound as its constituent material. Here, of hole-transporting compounds, examples of a hole-transporting compound having a low molecular weight may include various compounds described above as examples of the hole-transporting compound in the hole injection layer 3, aromatic diamines which contain two or more tertiary amines and in which two or more condensed aromatic rings are substituted with nitrogen atoms, typified by 4,4′-bis[N-(1-naphthyl)-N-phenylamino]biphenyl (so-called α-NPD), aromatic amine compounds having a starburst structure such as 4,4′,4″-tris(1-naphthylphenylamino)triphenylamine, aromatic amine compounds having a tetramer of triphenylamine, and spiro compounds such as 2,2′,7,7′-tetrakis-(diphenylamino)-9,9′-spirobifluorene.

In the light-emitting layer, one kind of the hole-transporting compound may be used alone, or two or more kinds thereof may be used in combination at any ratio.

The ratio of the hole-transporting compound in the light-emitting layer is usually 0.1% by weight or more and 65% by weight or less. When the amount of the hole-transporting compound is too small, the light-emitting layer may be subject to the effect of short circuit. When it is too large, the film thickness may be made uneven. When two or more kinds of hole-transporting compounds are used in combination, the total content thereof is set within the above-described range.

The light-emitting layer may contain an electron-transporting compound as its constituent material. Of electron-transporting compounds, examples of an electron-transporting compound having a low molecular weight may include 2,5-bis(1-naphthyl)-1,3,4-oxadiazole (so-called BND), 2,5-bis(6′-(2′,2″-bipyridyl))-1,1-dimethyl-3,4-diphenylsilole (so-called PyPySPyPy), bathophenanthroline (so-called BPhen), 2,9-dimethyl-4,7-diphenyl-1,10-phenanthroline (so-called BCP, bathocuproin), 2-(4-biphenylyl)-5-(p-tert-butylphenyl)-1,3,4-oxadiazole (so-called tBu-PBD), and 4,4′-bis(9H-carbazol-9-yl)biphenyl (so-called CBP). In the light-emitting layer, one kind of the electron-transporting compound may be used alone, or two or more kinds thereof may be used in combination at any ratio.

The ratio of the electron-transporting compound in the light-emitting layer is usually 0.1% by weight or more and 65% by weight or less. When the amount of the electron-transporting compound is too small, the light-emitting layer may be subject to the effect of short circuit. When it is too large, the film thickness may be made uneven. When two or more kinds of electron-transporting compounds are used in combination, the total content thereof is set within the above-described range.

When the light-emitting layer is formed by the wet coating method, the material for the light-emitting layer is dissolved in an appropriate solvent to prepare a composition for formation of a light-emitting layer, a film is formed using the composition by the wet coating method, and dried, and the solvent is removed to form the light-emitting layer. When the light-emitting layer is formed by the wet coating method, a coating solution for a light-emitting layer is prepared by dispersing or dissolving at least two kinds of solid contents (host material and guest material) to form a light-emitting layer as solutes in a solvent. The solvent used may be selected from the solvents used for the composition for formation of a hole injection layer.

The ratio of the solvent for a light-emitting layer to the composition for formation of a light-emitting layer to form a light-emitting layer is usually 0.01% by weight or more and 70% by weight or less. When a mixture of two or more kinds of solvents is used as the solvent for a light-emitting layer, the total amount of these solvents is set within the above-described range.

The film thickness of the light-emitting layer falls within a range of usually 3 nm or more, and preferably 5 nm or more, and usually 200 nm or less, and preferably 100 nm or less. When the film thickness of the light-emitting layer is too small, a defect may be generated in the film. When it is too large, the drive voltage may increase.

### [Electron Transport Layer]

The electron transport layer 7 is a layer provided to further improve the light-emitting efficiency of the organic EL panel, and therefore the electron transport layer 7 is formed from a compound capable of efficiently transporting an electron injected from the cathode toward the light-emitting layer between the electrodes to which an electric field is applied.

As the electron-transporting compound used for the electron transport layer, a compound that has high electron injection efficiency from the cathode 9 or the electron injection layer 8 and high electron mobility and is capable of efficiently transporting the injected electron is usually used. Examples of a compound satisfying these conditions may include metal complexes of Alq3 and 10-hydroxybenzo[h]quinoline, oxadiazole derivatives, distyryl biphenyl derivatives, silole derivatives, 3-hydroxyflavone metal complexes, 5-hydroxyflavone metal complexes, benzoxazole metal complexes, benzothiazole metal complexes, trisbenzimidazolylbenzene, quinoxaline compounds, phenanthroline derivatives, 2-tert-butyl-9,10-N,N′-dicyanoanthraquinonediimine, n-type hydrogenated amorphous silicon carbide, n-type zinc sulfide, and n-type zinc selenide.

One kind of material for the electron transport layer may be used alone, or two or more kinds thereof may be used in combination at any ratio.

A method for forming the electron transport layer is not limited. The electron transport layer can be formed by a wet coating method or a dry coating method. When the electron transport layer is formed by the wet coating method, the material for the electron transport layer is dissolved in an appropriate solvent to prepare a composition for formation of an electron transport layer, a film is formed using the composition by the wet coating method, and dried, and the solvent is removed to form the electron transport layer. The solvent used may be selected from the solvents used for the composition for formation of a hole injection layer.

The film thickness of the electron transport layer falls within a range of usually 1 nm or more, and preferably 5 nm or more, and usually 300 nm or less, and preferably 100 nm or less.

### [Electron Injection Layer]

The electron injection layer 8 fills a role of efficiently injecting an electron injected from the cathode into the light-emitting layer. In order to efficiently perform the electron injection, a material for formation of an electron injection layer is preferably a metal having a low work function. For example, an alkali metal such as sodium and cesium, an alkaline earth metal such as barium and calcium, a compound thereof (CsF, Cs₂CO₂, Li₂O, and LiF), or the like is used. It is preferable that the film thickness of the electron injection layer be usually 0.1 nm or more and 5 nm or less.

Further, when an organic electron transport compound typified by a nitrogen-containing heterocyclic compound such as bathophenanthroline and a metal complex such as aluminum complex of 8-hydroxyquinoline is doped with an alkali metal such as sodium, potassium, cesium, lithium, and rubidium, both improved electron injection and transport performance and excellent film quality can be achieved. In this case, the film thickness is usually 5 nm or more, and preferably 10 nm or more, and usually 200 nm or less, and preferably 100 nm or less.

One kind of the material for an electron injection layer may be used alone, or two or more kinds thereof may be used in combination at any ratio.

A method for forming the electron injection layer is not limited. The electron injection layer can be formed by a wet coating method or a dry coating method. When the electron injection layer is formed by the wet coating method, the material for an electron injection layer is dissolved in an appropriate solvent to prepare a composition for formation of an electron injection layer, a film is formed using the composition by the wet coating method, and dried, and the solvent is removed to form the electron injection layer. The solvent used may be selected from the solvents used for the composition for formation of a hole injection layer.

### Embodiments

Hereinafter, one example of Embodiments of the present invention will be described in detail with reference to the drawings.

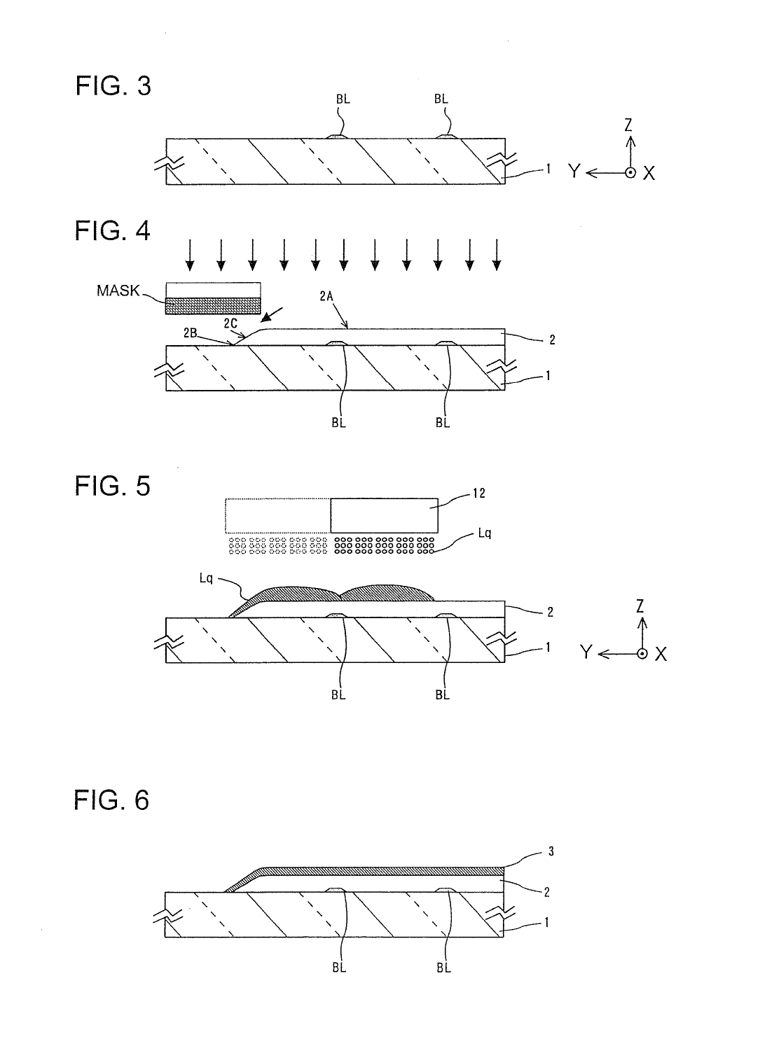

FIGS. 3 to 10 are each a cross-sectional view showing a substrate and a structure formed on the substrate in a production process of a method for producing the organic EL panel to which the present invention is applied. Such a production process will be described in the order of (a) an auxiliary electrode forming step, (b) an anode forming step, (c) a hole transport layer forming step, (d) a light-emitting layer forming step by coating, and (e) a light-emitting layer forming step by evaporation.

### (a) Auxiliary Electrode Forming Step

As shown in FIG. 3, a washed transparent substrate 1 made of a glass plate and having a thickness of 0.7 mm is first prepared. On the main surface of the substrate 1, auxiliary electrodes BL of aluminum-neodymium alloy (AlNd) are formed by a sputtering method using a contact mask or a contactless mask (not shown) disposed away from the main surface. A spraying material of an AlNd target is attached to a predetermined portion of the substrate through an opening of pattern of the mask, to obtain auxiliary electrodes having a tapered edge in the predetermined pattern. A plurality of band-shaped auxiliary electrodes BL are formed at certain pitches so as to elongate in parallel to an X direction on an X-Y surface of the substrate 1. The auxiliary electrodes BL are feed lines to an anode 2 to be formed in a next step, and are formed so that the width of the lines is smaller than the aligned pitches.

The auxiliary electrodes BL are formed so as to have the same cross-sectional shape, and arranged in parallel to one another. The surface of the substrate 1 is exposed between the auxiliary electrodes BL. For example, the thickness of each auxiliary electrode BL is 150 nm, the width thereof is 50 μm, and the distance between the adjacent auxiliary electrodes BL is 300 μm.

FIG. 3 shows a cross section along an arrangement direction Y that is perpendicular to an elongation direction X of the auxiliary electrodes BL. This is applicable to the following drawings.

### (b) Anode Forming Step

As shown in FIG. 4, a transparent anode 2 of In₂O₃—ZnO (IZO) is formed on the main surface of the substrate 1 and the auxiliary electrodes BL by a sputtering method using a mask disposed away from the main surface of the substrate 1. A spraying material of an IZO target is attached to the substrate 1 including the auxiliary electrodes BL through an opening of pattern of the mask, to obtain an IZO film having a tapered edge in the predetermined pattern as an anode 2 (transparent conductive film). The spraying material is carried into a gap between the mask and the substrate through the mask opening to form a tapered side surface 2C in which the film thickness gradually decreases from a smooth main surface 2A of the main surface of the transparent anode 2 toward an edge portion 2B.

The anode 2 is formed so as to cover the auxiliary electrodes BL and a substrate region (recess portion) between the adjacent auxiliary electrodes BL, and is in direct contact with the substrate 1 in the region between the auxiliary electrodes BL. The thickness of the anode 2 is, for example, 1,000 nm.

### (c) Hole Injection Layer and Hole Transport Layer Forming Step

The anode 2 is first subjected to irradiation with UV/O₃ (ultraviolet/ozone) as a pre-treatment using an excimer laser irradiation device (not shown) to clean the IZO surface.

As a material for a hole injection layer, an aqueous dispersion solution having a solid concentration of 1% by weight is prepared using poly(3,4-ethylenedioxythiophene) (PEDOT) as a host and polystyrenesulfonic acid (PSS) as a dopant.

After the pre-treatment, droplets Lq of a material for a hole injection layer are applied to the entire surface of the anode 2 with an inkjet head 12 of an inkjet device as shown in FIG. 5. For example, when the inkjet head 12 is transferred on the XY plane of the anode 2 through raster scan, edges of film of the applied droplets Lq are connected to form a droplet film so as to cover the edge portion of the anode 2 and the nearby substrate.

The droplet film is dried under vacuum using a vacuum drier at a gas pressure of 0.1 to 50 Pa over 2 minutes, and fired by a heat treatment at 230° C. over 1 hour. As shown in FIG. 6, the solvent of the droplet is evaporated to obtain a hardened hole injection layer 3 so as to cover the edge portion of the anode 2. At least part of an end portion of the hole injection layer 3 in a functional layered body is not in contact with the auxiliary electrodes BL and reaches the substrate 1.

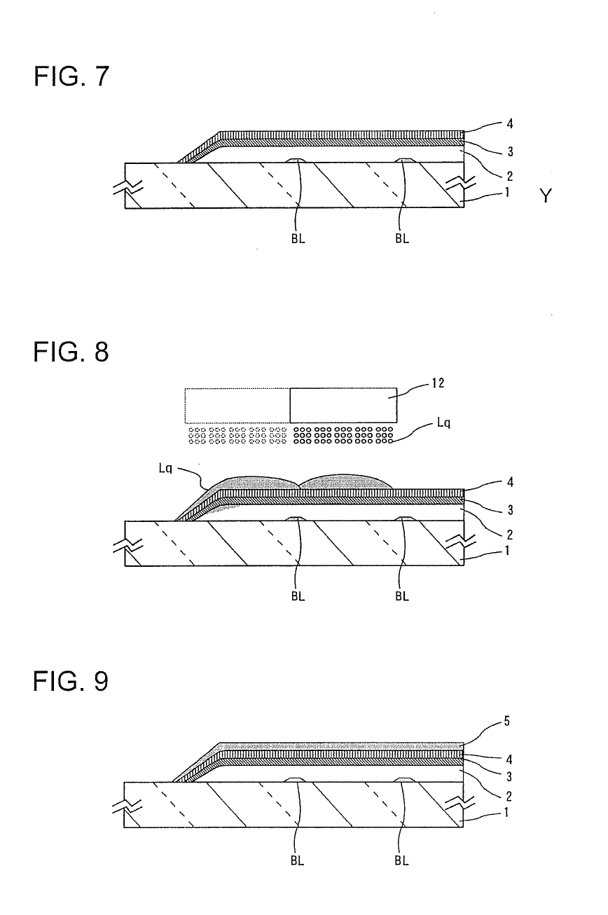

Like the hole injection layer, a hole transport layer 4 is formed by coating the entire surface of the hole injection layer 3 and the nearby substrate using droplets of organic solvent of 1,1-bis(4-di-p-tolylaminophenyl)cyclohexane at a predetermined concentration, followed by drying, as shown in FIG. 7. The thickness of each of the hole injection layer 3 and the hole transport layer 4 is 50 nm.

### (d) Light-Emitting Layer Forming Step by Coating

As a material for a light-emitting layer of emitting red light and green light, an organic solution having a solid concentration of 6% by weight is prepared using bis-(2-methyl-8-quinolinolato)(p-phenylphenolato)aluminum (Balq) as a host and tris[2-(4-n-hexylphenyl)quinoline)]iridium(III) (Hex-Ir(phq)₃) as a dopant.

Like the inkjet method described above, droplets Lq of a material for a light-emitting layer of emitting red light and green light are applied to the entire surface of the hole transport layer 4 with the inkjet head 12 as shown in FIG. 8.

The droplet film is dried under vacuum using a vacuum drier at a gas pressure of 0.1 to 50 Pa over 2 minutes, and fired by a heat treatment at 130° C. over 10 minutes. As a result, a hardened light-emitting layer 5 of emitting red light and green light that covers the hole transport layer 4 is obtained as shown in FIG. 9. The thickness of the light-emitting layer 5 of emitting red light and green light is, for example, 40 nm.

### (e) Light-Emitting Layer Forming Step by Evaporation

9,10-di(2-naphthyl)anthracene (so-called ADN) as a host and 4,4′-bis(2,2′-diphenylvinyl)biphenyl (so-called DPVBi) as a dopant at a concentration of 6% by weight are evaporated under vacuum on the light-emitting layer 5 of emitting red light and green light using a vacuum evaporator, and as a result, a blue light-emitting layer 6 having a thickness of, for example, 15 nm is formed.

Subsequently, Alq3 is evaporated under vacuum on the blue light-emitting layer 6 by a vacuum evaporation method, to form an electron transport layer 7 of Alq3 having a thickness of, for example, 30 nm.

Lithium fluoride (LiF) is then evaporated under vacuum on the electron transport layer 7 by the vacuum evaporation method, to form an electron injection layer 8 having a thickness of, for example, 1 nm.

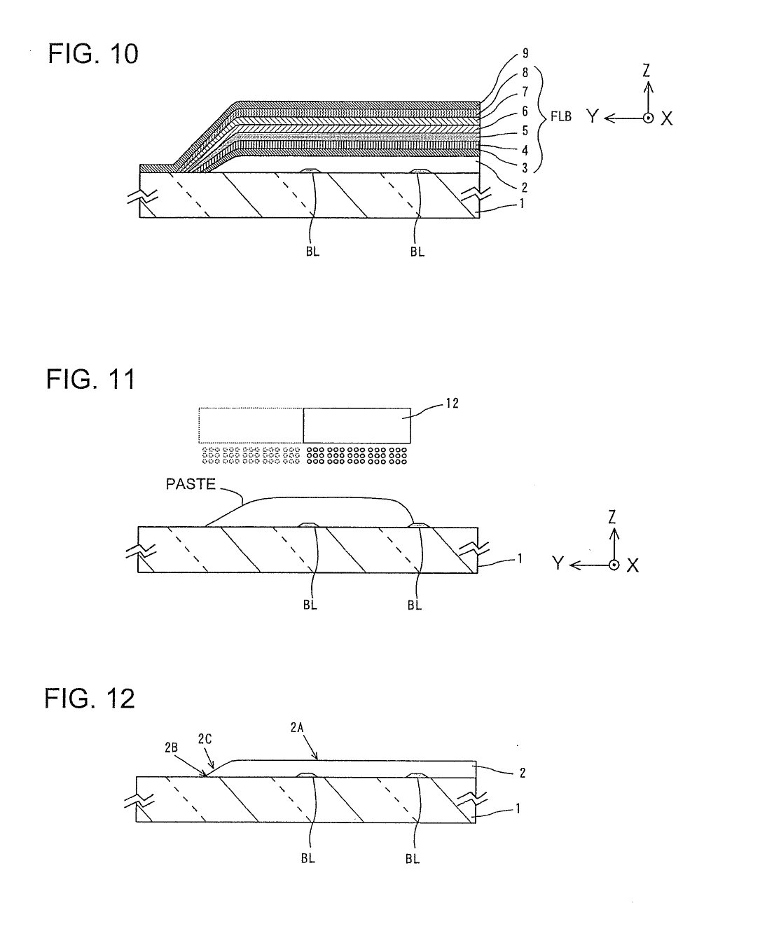

Aluminum (Al) is finally evaporated under vacuum on the electron injection layer 8 by the vacuum evaporation method using a mask having an opening of a predetermined pattern, to form a cathode 9 having a thickness of, for example, 80 nm. As shown in FIG. 10, a functional layered body FLB including the hole injection layer 3 to the electron injection layer 8 is formed. The cathode 9 is formed along the arrangement direction Y perpendicular to the elongation direction X of the auxiliary electrodes BL so as to intersect the transparent anode 2 (auxiliary electrodes BL) in a belt shape. At least part of the end portion of the cathode 9 that is an opposing electrode film is not in contact with the auxiliary electrodes BL and the transparent electrode 2 and reaches the substrate 1. A portion where the anode 2 and the cathode 9 overlap one another, with the functional layered body FLB being interposed therebetween, is defined as a light-emitting area of an organic EL panel.

According to such an embodiment, an organic EL panel is produced by (a) the auxiliary electrode forming step, (b) the anode forming step, (c) the hole transport layer forming step, (d) the light-emitting layer forming step by coating, and (e) the light-emitting layer forming step by evaporation. In the embodiment described above, the blue light-emitting layer 6 is formed by the vacuum evaporation method. However, all light-emitting layers are formed by a set of an inkjet coating step and a drying step, and coating and drying are repeated in turn for each functional layer that satisfies each function, and as a result, a multi-layered functional layered body FLB (hole injection layer 3/hole transport layer 4/light-emitting layer 5 of emitting red light and green light/blue light-emitting layer 6/electron transport layer 7) may be formed as shown in FIG. 10.

In the embodiment described above, a metal material such as AlNd is used as the auxiliary electrodes BL, the anode 12 of transparent conductive film is layered on the auxiliary electrodes BL, and light emitted from the light-emitting layers is diffused by the auxiliary electrodes BL. Therefore, the aperture ratio of the organic EL panel can be improved.

For example, in a conventional organic LED, an insulating bank material is used, and as the bank material, a material capable of absorbing in a visible light range, such as a polyimide material, is often used. Therefore, the appearance may be impaired in terms of the hue relative to the metallic color of the cathode. Further, because of the presence of the material capable of absorbing in the visible light range, emitted light may be lost in the bank. On the other hand, metal such as AlNd is used as the auxiliary electrodes BL in the embodiment described above, and therefore, the color is the same as the metallic color of Al of the cathode 9 and the appearance is not affected. Further, even if emitted light is diffused by the auxiliary electrodes BL, the light is not lost and emitted from the organic EL panel. Therefore, the aperture ratio higher than that of the conventional organic EL can be achieved. Further, the electric resistivity of the material for the auxiliary electrodes BL is lower than that of the material for the anode 2, and the anode 2 is in direct contact with the auxiliary electrodes BL. Therefore, electric power can be effectively supplied to the organic EL panel. Furthermore, because of the increased aperture ratio, as described above, the emitted light can be efficiently released. Therefore, the power consumption can be decreased for obtaining a desired amount of light as compared with a conventional element.

In the embodiment described above, two layers of the hole injection layer 3 and the hole transport layer 4 are formed on the anode 2 (transparent conductive film). However, the present invention is not limited to the formation of two layers. Only one layer of the hole injection layer and the hole transport layer, three or more layers including the hole injection layer, the hole transport layer, and an electron block layer (not shown) may be formed below a light-emitting layer.

The materials for the substrate 1, the auxiliary electrodes BL, the anode 2, the hole injection layer 3, the hole transport layer 4, the light-emitting layer 5 of emitting red light and green light, the blue light-emitting layer 6, the electron transport layer 7, the electron injection layer 8, and the cathode 9 in the embodiments described above are each not limited to those described above. For example, as the material for the auxiliary electrodes BL, metal such as Al, Ag, Mo, Ti, Pt, and Au or an alloy thereof may be used.

The method for forming each film in each step, and the conditions such as the width and the thickness of each film, the heating temperature, and the heating time, shown in the embodiments described above, serve only as one example, and the present invention is not limited to these.

Further, the auxiliary electrodes are not necessarily limited to have the same cross-sectional shape, and do not necessarily have the same length in a line elongation direction.

### Other Embodiments

In the embodiments described above, the anode 2 is patterned by a sputtering method using a mask. The anode 2 can be formed by a wet coating method such as screen printing, an inkjet method, a spray-coating method, a roll-coating method, and printing using a plate, in addition to the sputtering method.

For example, the auxiliary electrodes BL are formed in the auxiliary electrode forming step shown in FIG. 3, and an IZO paste is then applied to the auxiliary electrodes BL by printing in accordance with the inkjet method, to form an IZO paste-coating film.

For example, droplets Lq of the IZO paste are applied to the substrate 1 and the auxiliary electrodes BL with an inkjet head 12 in a predetermined pattern, as shown in FIG. 11. The substrate 1 is dried (for example, at 150 to 200° C.), and fired (for example, at 400 to 600° C.), to form an anode 2 in the predetermined pattern so as to cover the substrate 1 and the auxiliary electrodes BL, as shown in FIG. 12. In this production method, the anode 2 can be formed without a mask and an etching step. Therefore, the formation of the anode 2 is made simple. By dripping caused by the printing, an anode 2 (transparent conductive film) of IZO that has a smooth main surface 2A and a tapered side surface 2C in which the film thickness gradually decreases toward an edge portion 2B can be easily obtained.

### EXPLANATION OF REFERENCE NUMERALS

1 Substrate
2 Anode
3 Hole injection layer
4 Hole transport layer
5 Light-emitting layer of emitting red light and green light
6 Blue light-emitting layer
7 Electron transport layer
8 Electron injection layer
9 Cathode
BL Auxiliary electrodes

1. An organic EL panel including a substrate, a transparent conductive film layered on the substrate, a functional layered body that is layered on the transparent conductive film and includes at least one light-emitting layer, and an opposing electrode film layered on the functional layered body, wherein the light-emitting layer that is disposed between the transparent conductive film and the opposing electrode film and overlaps the transparent conductive film and the opposing electrode film serves as a light-emitting portion, the organic EL panel comprising:
at least one auxiliary electrode that is formed on the substrate below the light-emitting portion and directly covered with the transparent conductive film,
wherein the transparent conductive film has a film thickness more than that of the one auxiliary electrode, and
a side surface of the transparent conductive film is covered with the functional layered body.

2. The organic EL panel according to claim 1, wherein a layer in contact with the transparent conductive film in the functional layered body is formed by a wet coating method and has a film thickness more than that of the at least one auxiliary electrode.

3. The organic EL panel according to claim 1, wherein the transparent conductive film is formed by a wet coating method or a sputtering method using a mask.

4. The organic EL panel according to claim 1, wherein at least part of the transparent conductive film has a tapered side surface in which the film thickness gradually decreases toward an edge, and
the tapered side surface of the transparent conductive film is covered with the functional layered body.

5. The organic EL panel according to claim 4, wherein the functional layered body does not contact the at least one auxiliary electrode and the functional layered body contacts the substrate.

6. The organic EL panel according to claim 4, wherein the opposing electrode film does not contact the at least one auxiliary electrode and the opposing electrode film contacts the substrate.

7. The organic EL panel according to claim 1, wherein the transparent conductive film has a film thickness of 1 μm to 5 μm.

8. A method for producing an organic EL panel, the organic EL panel including a substrate, a transparent conductive film layered on the substrate, a functional layered body that is layered on the transparent conductive film and includes at least one light-emitting layer, and an opposing electrode film layered on the functional layered body, wherein the light-emitting layer that is disposed between the transparent conductive film and the opposing electrode film and overlaps the transparent conductive film and the opposing electrode film serves as a light-emitting portion, the method comprising:
forming at least one auxiliary electrode on part of a main surface of the substrate;
forming the transparent conductive film on the substrate and the auxiliary electrode; and
forming the functional layered body that covers the transparent conductive film,
wherein in the step of forming the transparent conductive film, the transparent conductive film is formed by a wet coating method so that the transparent conductive film has a film thickness more than that of the at least one auxiliary electrode and the at least one auxiliary electrode is completely covered with the transparent conductive film below the light-emitting portion.

9. A method for producing an organic EL panel, the organic EL panel including a substrate, a transparent conductive film layered on the substrate, a functional layered body that is layered on the transparent conductive film and includes at least one light-emitting layer, and an opposing electrode film layered on the functional layered body, wherein the light-emitting layer that is disposed between the transparent conductive film and the opposing electrode film and overlaps the transparent conductive film and the opposing electrode film serves as a light-emitting portion, the method including:
forming at least one auxiliary electrode on part of a main surface of the substrate;
forming the transparent conductive film on the substrate and the auxiliary electrode; and
forming the functional layered body that covers the transparent conductive film,
wherein in the step of forming the transparent conductive film, the transparent conductive film is formed by a sputtering method using a mask so that the transparent conductive film has a film thickness more than that of the at least one auxiliary electrode and the at least one auxiliary electrode is completely covered with the transparent conductive film below the light-emitting portion.

10. An organic EL panel, comprising:
a flexible substrate;
a transparent electrode layered on a surface of the flexible substrate;
a functional layered body that is layered on the transparent electrode;
an opposing electrode film layered on the functional layered body; and
at least one auxiliary electrode that is covered with the transparent electrode,
wherein the transparent electrode covering the at least one auxiliary electrode has a film thickness greater than that of the at least one auxiliary electrode.

11. The organic EL panel according to claim 10, wherein the functional layered body covers a side surface of the transparent electrode.

12. The organic EL panel according to claim 11, wherein the side surface of the transparent electrode tapers to an edge portion of the transparent electrode at the surface of the flexible substrate.

13. The organic EL panel according to claim 12, wherein the transparent electrode is formed by a wet coating process.

14. The organic EL panel according to claim 10, wherein the flexible substrate comprises one of a transparent plate of synthetic resin, a plastic sheet, and a plastic film.

15. The organic EL panel according to claim 10, wherein the synthetic resin comprises a resin selected from the group consisting of polyester, polymethacrylate, polycarbonate, and polysulfone.

16. The organic EL panel according to claim 10, wherein at least one auxiliary electrode comprises a metal material capable of diffusing light in the visible spectrum.

17. The organic EL panel according to claim 16, wherein the metal material comprises at least one of Ag and Al.

18. The organic EL panel according to claim 10, wherein the at least one auxiliary electrode comprises a plurality of parallel auxiliary electrodes, and
a pitch of the plurality of parallel auxiliary electrodes is greater that a width of an auxiliary electrode.
